(19) United States
(12) Patent Application Publication
(10) Pub. No.: US 2021/0083225 A1
(43) Pub. Date: Mar. 18, 2021

(54) DISPLAY PANEL AND MANUFACTURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Tianfu GUO, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 16/960,101

(22) PCT Filed: Sep. 10, 2019
(86) PCT No.: PCT/CN2019/105120

§ 371 Date: Jul. 6, 2020

(30) Foreign Application Priority Data
Aug. 9, 2019 (CN) 201910733475.4

(51) Int. Cl. H01L 51/52; H01L 51/56

(52) U.S. Cl. CPC H01L 51/5253; H01L 51/56

(57) ABSTRACT

The present invention provides a display panel and manufacturing method of the display panel. The display panel includes a substrate and a TFE layer. The TFE layer includes a first inorganic layer, an organic layer, and a laminated film layer. The manufacturing method of the display panel includes a substrate provision step and a TFE layer formation step. The TFE layer formation step includes a first inorganic layer formation step, a laminated film layer formation step, an organic layer formation step, and a second inorganic layer formation step.

### FIELD OF THE DISCLOSURE

The present invention relates to a display device and in particular, to a display panel and a manufacturing method thereof.

### DESCRIPTION OF THE RELATED ART

Compared with conventional liquid crystal displays (LCDs), organic light emitting diode (OLED) display panels have advantages such as light weight, wide viewing angles, fast response time, low temperature operations, and high luminous efficiency. Therefore, in the display industry, OLED has been regarded as the next generation of new display technology, especially OLED can be flexible on the flexible substrate, which is a unique advantage of OLED. In order to realize this advantage (flexible display) of OLED, thin film encapsulation (TFE) technology is an essential core technology.

The display panel is vulnerable to water/oxygen present in the environment. Ambient water and oxygen generally intrude from two paths: the first path is that water and oxygen directly penetrate a TFE layer from top to bottom into the inside of the display panel; the second path is that water and oxygen enter and erode the OLED from a lateral side of the TFE layer.

A display panel normally includes a glass substrate, an array substrate, a light-emitting layer, and a thin film encapsulation (TFE) layer. The TFE layer comprises a first inorganic layer, an organic layer, and a second inorganic layer, and is a sandwich structure that is a common TFE structure in the industry. In the industry, a water vapor transmission rate (WVTR) of this sandwich structure can be less than 5E-4 g/m2/day. The first inorganic layer and the second inorganic layer are used to prevent intrusion of water and oxygen into the organic layer inside the display panel. Since the organic layer is porous, it cannot block water and oxygen. As a result, the display panel has poor water/oxygen barrier properties.

In conventional techniques, the TFE structure includes an aluminum oxide layer and a polypropylene (PP) layer stacked on each other. The TFE structure theoretically has good water/oxygen barrier properties, but in fact, a foreign matter inevitably appearing in a manufacturing process cannot be effectively wrapped. As a result, the actual water/oxygen barrier effects are often poor.

In patent no. US20150021565 and patent no. US20150048331, the structure of the TFE layer comprises a first inorganic layer, a first organic layer, a second inorganic layer, a second organic layer, and a third inorganic layer, wherein the first inorganic layer is made of aluminum oxide. The main disadvantage of the structure of the TFE layer is that the structure having the inorganic layer and the organic layer alternately stacked on each other is too thick, resulting in relatively poor bending ability, and the layers tends to be excessively stressed. This may even cause a lower light-emitting layer of the display panel to deform, which is not conducive to the long-term development of flexible display panels.

### SUMMARY

The present invention provides a display panel and a manufacturing method thereof, so as to solve problems in conventional techniques, such as poor water/oxygen barrier properties, low flexibility, and poor optical performance of the display panel.

Accordingly, the present invention provides a display panel comprises a substrate and a thin film encapsulation layer. The thin film encapsulation layer comprises a first inorganic layer, an organic layer, a second inorganic layer, and a laminated film layer. The first inorganic layer is disposed on a side surface of the substrate. The organic layer is disposed on one side of the first inorganic layer away from the substrate, and the organic layer comprises a patterned surface. The second inorganic layer is disposed on one side of the organic layer away from the first inorganic layer. The laminated film layer is disposed between the organic layer and the first inorganic layer or between the organic layer and the second inorganic layer. The laminated film layer comprises a dense layer and an interlayer, the dense layer is disposed on the first inorganic layer or the second inorganic layer, one side of the interlayer is attached to the dense layer, and another side of the interlayer is attached to the organic layer.

Preferably, the organic layer comprises two or more protrusions protruding from the patterned surface.

Preferably, the patterned surface is in contact with the laminated film layer or in contact with the second inorganic layer.

Preferably, the dense layer is made of aluminum oxide and/or titanium oxide.

Preferably, the interlayer is made of silicon oxide and/or silicon oxynitride.

Preferably, a thickness of the dense layer is less than 200 nm, a thickness of the interlayer is less than 150 nm, and a refractive index of the interlayer is greater than 1.6.

Accordingly, the present invention further provides a manufacturing method of a display panel, comprising steps as follows:

a substrate provision step for providing a substrate; and

a thin film encapsulation layer formation step for forming a thin film encapsulation layer on an upper surface of the substrate;

wherein the thin film encapsulation layer formation step comprises steps as follows:

a first inorganic layer formation step for forming a first inorganic layer on the upper surface of the substrate;

a laminated film layer formation step for forming a laminated film layer on an upper surface of the first inorganic layer;

an organic layer formation step for forming an organic layer on an upper surface of the laminated film layer and patterning a surface of the organic layer; and

a second inorganic layer formation step for forming a second inorganic layer on an upper surface of the organic layer.

Preferably, the laminated film layer formation step comprises steps as follows:

a dense layer formation step for depositing a dense layer on the upper surface of the first inorganic layer by an atomic deposition method; and

an interlayer formation step for depositing an interlayer on the upper surface of the dense film layer by a chemical vapor deposition method;

wherein in the organic layer formation step, the organic layer is deposited on an upper surface of the interlayer, and a surface of the organic layer is patterned.

Accordingly, the present invention still provides a manufacturing method of a display panel, comprising steps as follows:

a substrate provision step for providing a substrate; and

a thin film encapsulation layer formation step for forming a thin film encapsulation layer on an upper surface of the substrate;

wherein the thin film encapsulation layer formation step comprises steps as follows:

a first inorganic layer formation step for forming a first inorganic layer on the upper surface of the substrate;

an organic layer formation step for forming an organic layer on an upper surface of the first inorganic layer and patterning a surface of the organic layer;

a laminated film layer formation step for forming a laminated film layer on an upper surface of the organic layer; and

a second inorganic layer formation step for forming a second inorganic layer on the upper surface of the organic layer.

Preferably, the laminated film layer formation step comprises steps as follows:

an interlayer formation step for depositing an interlayer on an upper surface of the first inorganic layer by a chemical vapor deposition method; and

a dense layer formation step for depositing a dense layer on an upper surface of the interlayer by an atomic deposition method;

wherein in the second inorganic layer formation step, a second inorganic layer is deposited on an upper surface of the laminated film layer.

Advantageous effects of the present invention: The present invention provides the display panel and the manufacturing method of the display panel. On the one hand, the stress of the layers is released by means of the patterned surface on the organic layer, and a risk of breakage of the TFE layer from bending of the display panel is lowered, thereby improving reliability of the TFE layer and enhancing optical performance of the display panel. On the other hand, by providing a laminated film layer between the adjacent organic layer and inorganic layer, adhesion between the layers is improved, the TFE layer has better water/oxygen barrier properties, thereby further improving reliability of the TFE layer.

### BRIEF DESCRIPTION OF THE DRAWINGS

In order to more clearly illustrate the embodiments of the present disclosure or related art, figures which will be described in the embodiments are briefly introduced hereinafter. It is obvious that the drawings are merely for the purposes of illustrating some embodiments of the present disclosure, a person having ordinary skill in this field can obtain other figures according to these figures without an inventive work or paying the premise.

FIG. 1 is a schematic structural view illustrating an OLED display device according to a first embodiment of the present invention;

FIG. 2 is another schematic structural view illustrating the OLED display device according to the first embodiment;

FIG. 3 is a process flow diagram illustrating a manufacturing method of a display panel according to the first embodiment;

FIG. 4 is a process flow diagram illustrating a thin film encapsulation (TFE) layer formation step according to the first embodiment;

FIG. 5 is a graph showing a light transmittance of the TFE layer according to the first embodiment;

FIG. 6 is a graph showing a light emission spectrum of the TFE layer according to the first embodiment;

FIG. 7 is a schematic structural view illustrating the TFE layer according to a second embodiment; and

FIG. 8 is a process flow diagram illustrating the TFE layer formation step according to the second embodiment.

### DETAILED DESCRIPTION OF THE EMBODIMENTS

Preferable embodiments of the present invention are described in detail below with reference to the accompanying drawings, so that the technical content of the present disclosure will be clearer, and those skilled in the art will more readily understand how to implement the invention. The present invention may, however, be embodied in many different forms and embodiments, and the scope of the invention is not limited to the embodiments described herein. A description of the embodiments below is not intended to limit the protection scope of the invention.

### First Embodiment

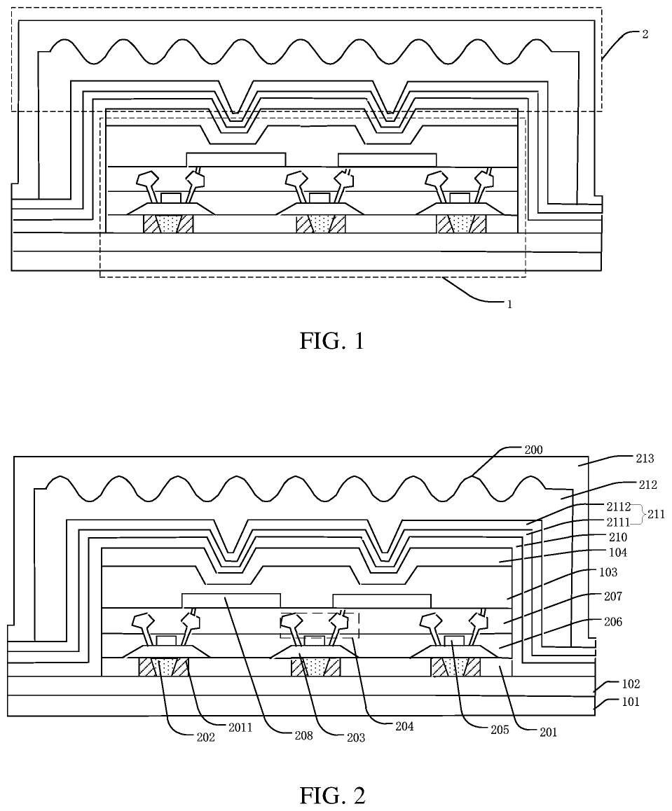

As shown in FIG. 1, the present embodiment provides a display panel. The display panel comprises a substrate 1 and a thin film encapsulation (TFE) layer 2. The TFE layer 2 is disposed on an upper surface of the substrate 1.

Referring to FIG. 2, the substrate 1 comprises a glass underlay 101, a polyimide (PI) base, a plurality of thin film transistors (TFTs), a pixel defining layer 103, and a light-emitting layer 104.

The glass substrate 101 is a glass plate in prior arts. The PI substrate 102 is a flexible substrate whose material is mainly polyimide (PI), and the PI material can effectively improve a light transmittance. Each of the TFTs includes an active layer 201 (P-type doping), a polysilicon layer 202, a dielectric layer 203, a source/drain electrode 204, a gate electrode 205, an insulating layer 206, a planarization layer 207, and an anode 208. In details, the active layer 201 is provided with a doping region 2011. The doping region 2011 is doped with a P-type impurity or an N-type impurity, which is a connection region for a source/drain electrode of a metal-oxide-semiconductor (MOS) transistor and is connected to the source/drain electrode 204. The polysilicon layer 202 is a connection region for a gate electrode of the MOS transistor and is connected to the gate electrode 205. The dielectric layer 203 is used to insulate the source/drain electrode 204 from the gate electrode 205 to avoid a short circuit resulting from contact between the electrodes. The insulating layer 206 is disposed on upper surfaces of the active layer 202, the dielectric layer 203, and the gate electrode 205, and is penetrated by the source/drain electrode 204. The planarization layer 207 is disposed on upper surfaces of the source/drain electrode 204 and the insulating layer 206. The anode 208 is disposed on upper surfaces of the planarization layer 207 and the anode 208. The planarization layer 207 is generally made of a composite material of polymethyl methacrylate or nanoparticles, and has good heat resistance. The pixel defining layer 103 is disposed on the upper surface of the planarization layer 207. The light-emitting layer 104 is disposed on an upper surface of the pixel defining layer 103, and a cathode (not illustrated) is disposed in the light-emitting layer 104. The light-emitting layer 104 comprises a hole injection layer, a hole transport layer, an organic light-emitting layer, an electron transport layer, and an electron injection layer, so that an OLED device has advantages such as good stability, high color purity, good color temperature, and a long lifespan.

Referring to FIG. 2, the TFE layer 2 comprises a first inorganic layer 210, an organic layer 212, and a second inorganic layer 213. The first inorganic layer 210 is disposed on an upper surface of the substrate 1. The organic layer 212 is disposed above the first inorganic layer 210. The second inorganic layer 213 is disposed on an upper surface of the organic layer 212. A laminated film layer 211 is disposed between the first inorganic layer 210 and the organic layer 212.

The laminated film layer 211 comprises a dense layer 2111 and an interlayer 2112. The TFE layer comprises, from bottom to top, the first inorganic layer 210, the dense layer 2111, the interlayer 2112, the organic layer 212, and the second inorganic layer 213.

The first inorganic layer 210 is formed on the upper surface of the substrate by chemical vapor deposition (CVD) or physical vapor deposition (PVD). A thickness of the first inorganic layer 210 is less than 2 μm, and the first organic layer 210 can be made of an inorganic compound such as silicon nitride (SiN), silicon oxynitride (SiON) or silicon monoxide (SiO). The first inorganic layer 210 can protect against intrusion of ambient water/oxygen and also improve optical performance of the display panel.

The dense layer 2111 is deposited on an upper surface of the first inorganic layer 210 by an atomic deposition method. The dense layer 2111 is made of aluminum oxide and/or titanium oxide; however, the present invention is not limited to these materials. The dense layer 2111 has a thickness less than 200 nm and a refractive index greater than 1.6. The dense layer 2111 has good water/oxygen barrier properties and an excellent light transmittance. The dense layer 2111 has a light transmittance of more than 99% and a wavelength in a range from 400 to 800 nm. In the present embodiment, the refractive index of the dense layer 2111 is greater than a refractive index of the first inorganic layer 210, and the dense layer 2111 can effectively make up for a texture defect of the first inorganic layer 210 and improve water/oxygen barrier properties of the TFE layer. In the present embodiment, the thickness of the dense layer 2111 is preferably 80 nm, 95 nm, or 100 nm, but can also be other thickness as long as the water/oxygen barrier properties of the TFE layer can be effectively improved.

An interlayer 2112 is deposited on an upper surface of the first dense layer 2111 by chemical vapor deposition. The interlayer 2112 has a thickness less than 150 nm and is made of silicon oxide and/or silicon oxynitride; however, material of the interlayer 2112 is not limited to the materials mentioned in the present disclosure. The interlayer 2112 has hydrophobicity and can improve physical force interactions between the layers, thereby improving adhesion between the layers.

The organic layer 212 is attached to an upper surface of the interlayer 2112 by deposition. The organic layer 212 comprises a patterned surface including multiple protrusions 200 distributed in a Z shape, a S shape, or an arc shape, which can better release stress and thereby improve the optical performance of the display panel. In the present invention, a shape of the protrusion is not limited, and those skilled in the art can design the shape according to actual needs, as long as the optical performance of the display panel can be improved.

Material of the organic layer 212 can be hexamethyldisiloxane (HMDSO), an aluminum-based organic-inorganic composite (alucone), epoxy resin, acrylic materials, and an organic substance containing silicon. Therefore, the organic layer 212 can wrap a foreign matter appearing during deposition, alleviate the stress generated between the layers, and lower a risk of the display panel being broken by bending, thereby improving the flexibility and optical performance of the display panel.

Furthermore, in the present embodiment, an interlayer 2112 is disposed between the dense layer 2111 and the organic layer 212, so the adhesion between the dense layer 2111 and the organic layer 212 can be improved, and the water/oxygen barrier properties of the TFE layer are improved, thereby improving reliability of the TFE layer.

The second inorganic layer 213 is formed on the upper surface of the organic layer 212 by chemical vapor deposition (CVD), physical vapor deposition (PVD), or other suitable method. In other words, the second inorganic layer 123 is attached to the patterned surface. The second inorganic layer 213 has a thickness less than 2 μm and is made of an inorganic compound such as silicon nitride (SiN), silicon oxynitride (SiON) or silicon monoxide (SiO). The second inorganic layer 213 can block water/oxygen. In addition, the organic layer 212 includes the patterned surface, and therefore, on the one hand, a contact area between the second inorganic layer 213 and the organic layer 212 is increased to effectively block water and oxygen, and on the other hand, adhesion between the second inorganic layer 213 and the organic layer 212 is improved, stress between the layers is alleviated, flexibility of the TFE layer is improved, and optical performance of the display panel is also improved.

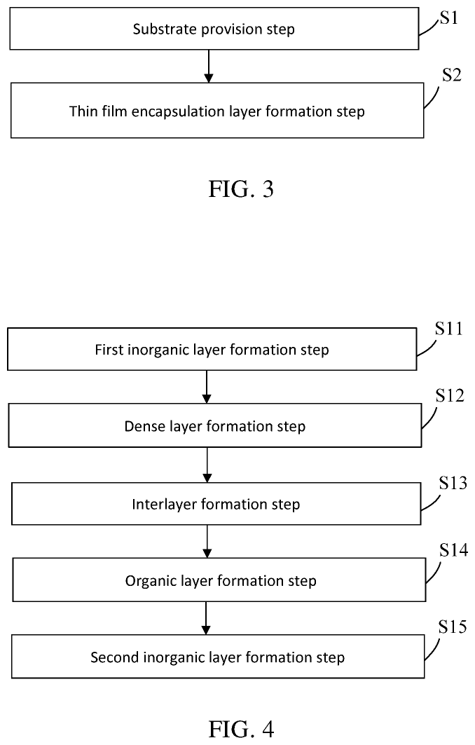

Referring to FIG. 3, the present invention further provides a manufacturing method of a display panel, comprising steps S1 and S2.

Step S1: a substrate provision step for providing a substrate.

Step S2: a thin film encapsulation layer formation step for forming a thin film encapsulation (TFE) layer on an upper surface of the substrate.

Referring to FIG. 4, the TFE layer formation step comprises steps S11 to S15 as follows.

Step S11: a first inorganic layer formation step for forming a first inorganic layer on the upper surface of the substrate. In detail, the first inorganic layer is deposited on the substrate by chemical vapor deposition (CVD), physical vapor deposition (PVD), or other suitable method. The first inorganic layer has a thickness of less than 2 μm and is made of an inorganic compound such as silicon nitride (SiN), silicon oxynitride (SiON), or silicon monoxide (SiO). The first inorganic layer can protect against intrusion of water/oxygen and improve performance of the display panel.

Step S12: a dense layer formation step for depositing a dense layer on an upper surface of the first inorganic layer by an atomic deposition method.

The dense layer is made of aluminum oxide and/or titanium oxide, but can also be made of other suitable materials. The dense layer has a thickness of less than 200 nm and a refractive index of more than 1.6. The dense layer has good water/oxygen barrier properties and an extremely high light transmittance. The dense layer 2111 has a light transmittance of more than 99% and a wavelength in a range from 400 to 800 nm. The refractive index of the dense layer is greater than a refractive index of the first inorganic layer, which can effectively make up for a texture defect of the first inorganic layer film and can effectively improve the water/oxygen barrier properties of the TFE layer. In the present embodiment, the thickness of the dense film layer is preferably 80 nm, 95 nm, and 100 nm, but can also be other thickness, as long as the water/oxygen barrier properties of the TFE layer can be effectively improved.

Step S13: an interlayer formation step for depositing an interlayer on the upper surface of the dense layer by a chemical vapor deposition method. The interlayer is made of silicon oxide and/or silicon oxynitride; however, material of the interlayer is not limited to the materials mentioned in the present disclosure. The interlayer has a thickness less than 150 nm and is mainly made of silicon oxide; however, the present invention is not limited to the materials of the interlayer 2112 mentioned herein. The interlayer 2112 has hydrophobicity and can improve physical force interactions between the layers, thereby improving adhesion between the layers.

Step S14: an organic layer formation step for depositing an organic layer on an upper surface of the laminated film layer.

An organic layer is formed on the upper surface of the laminated film layer by ink jet printing (IJP), chemical vapor deposition (CVD), or evaporation. Specifically, the organic layer is formed on the upper surface of the interlayer, and a surface of the organic layer is patterned by using a mask to make the surface of the organic layer be a patterned surface. The patterned surface includes multiple protrusions which are continuously distributed in a Z shape, an S shape, and an arc shape, thereby better releasing stress and improving optical performance of the display panel. In the present embodiment, a shape of the protrusion is not limited, and those skilled in the art can design the shape of the protrusion according to actual needs, as long as the optical performance of the display panel can be improved.

The organic layer can be made of hexamethyldisiloxane (HMDSO), aluminum-based organic-inorganic composite (alucone), epoxy resin, acrylic materials, and an organic material containing silicon. Therefore, the organic layer can wrap a foreign matter appearing during deposition, alleviate the stress generated between the layers, and lower a risk of the display panel being broken by bending, thereby improving flexibility and optical performance of the display panel.

Step S15: a second inorganic layer formation step for forming a second inorganic layer on the upper surface of the organic layer.

A second inorganic layer is deposited on the upper surface of the organic layer by chemical vapor deposition (CVD), physical vapor deposition (PVD), or other suitable method. The second inorganic layer has a thickness of less than 2 μm and may be made of an inorganic compound such as silicon nitride (SiN), silicon oxynitride (SiON), or silicon monoxide (SiO). The second inorganic layer can protect against intrusion of water/oxygen and can improve the optical performance of the display panel.

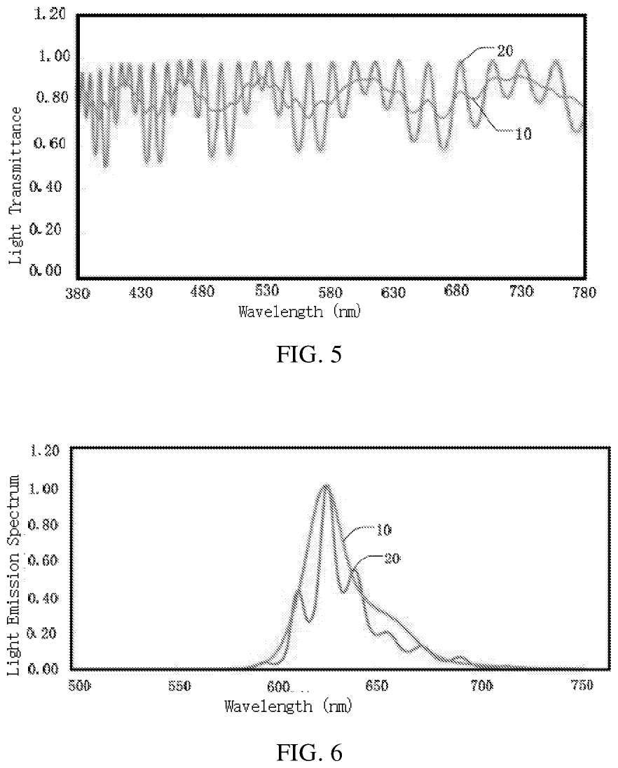

As shown in FIG. 5, by comparing a light transmittance of a first TFE layer 10 provided in the present embodiment with a light transmittance of a second TFE layer 20 of a prior art, it is apparent that the light transmittance of the first TFE layer 10 has a small fluctuation range, and the light transmittance of the first TFE layer 10 is remarkably improved, so that the TFE layer has excellent water/oxygen barrier properties, and the display panel has a good encapsulation quality.

As shown in FIG. 6, by comparing a light emission spectrum of the first TFE layer 10 of the present embodiment with a light emission spectrum of the second TFE layer 20 of the prior art, it is apparent that the first TFE layer 10 has better luminous efficiency. In the present embodiment, by providing the patterned surface on the organic layer, stress of the layers is released better, the TFE layer has a low risk of breakage during bending, the reliability of the TFE layer is improved, and the optical performance of the display panel is enhanced.

The present invention provides the display panel and the manufacturing method thereof. On one hand, the present invention better releases the stress of the layer by means of the patterned surface of the organic layer, and reduces a risk of breakage of the TFE layer from bending of the display panel. Therefore, reliability of the TFE layer and optical performance of the display panel are improved. On the other hand, by providing the laminated film layer between the organic layer and the inorganic layer adjacent to each other, adhesion between the adjacent layers is improved, the TFE layer can better block water/oxygen, and thereby the reliability of the TFE layer is improved.

### Second Embodiment

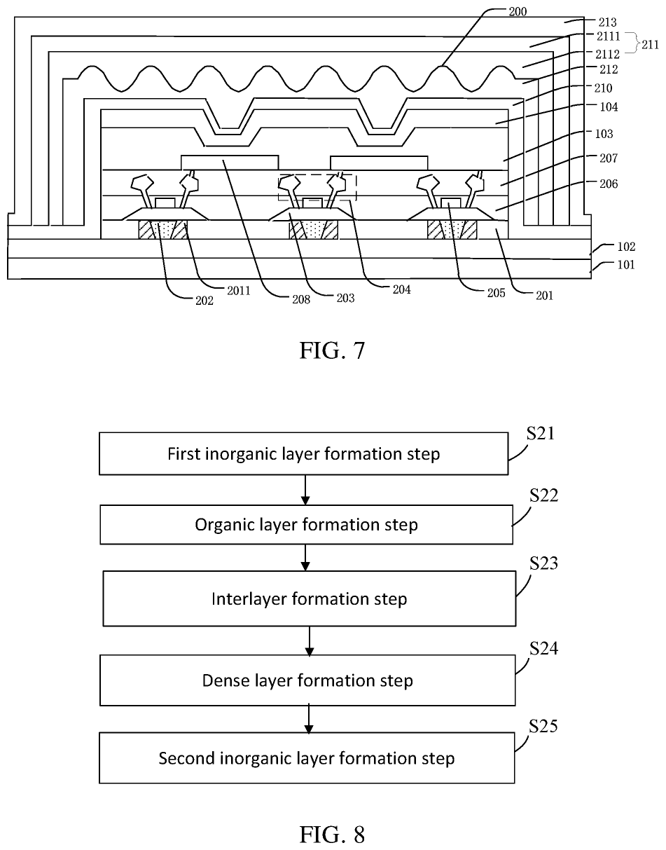

As shown in FIG. 7, the second embodiment provides a display panel which comprises most technique features of the display panel. The second embodiment is different from the first embodiment in that, the laminated film layer 211 is disposed between the second inorganic layer 210 and the organic layer 212, instead of being disposed between the first inorganic layer 210 and the organic layer 212.

As shown in FIG. 7, the TFE layer in the display panel includes, from bottom to top, the first inorganic layer 210, the organic layer 212, the laminated film layer 211, and a second inorganic layer 213. The laminated film layer 211 comprises the dense layer 2111 and the interlayer 2112.

In the present embodiment, the interlayer 2112 is disposed on the upper surface of the organic layer 212, and the dense layer 2111 is disposed on an upper surface of the interlayer 2112. Since the adhesion between the dense layer 2111 and the organic layer 212 is weak, the adhesion between the dense layer 2111 and the organic layer 212 can be enhanced by providing the interlayer 2112, so that the TFE layer has improved water/oxygen barrier properties, and thereby the reliability of the TFE layer is improved.

The second embodiment further provides a manufacturing method of the display panel, comprising the following steps S1 and S2, as shown in FIG. 3.

Step S1: a substrate provision step for providing a substrate.

Step S2: a thin film encapsulation (TFE) layer formation step for forming a TFE layer on an upper surface of the substrate.

Referring to FIG. 8, the TFE layer formation step comprises the following steps S21 to S25.

Step S21: a first inorganic layer formation step for forming a first inorganic layer on the upper surface of the substrate.

Step S22: an organic layer formation step for forming an organic layer on an upper surface of the first inorganic layer and patterning a surface of the organic layer.

Step S23: an interlayer formation step for depositing an interlayer on the upper surface of the first inorganic layer by a chemical vapor deposition method.

Step S24: a dense layer formation step for depositing a dense layer on the upper surface of the interlayer by an atomic deposition method.

Step S25: a second inorganic layer formation step for forming a second inorganic layer on an upper surface of the water-absorbent laminated film layer.

Steps S21 to S25 are different from steps S11 to S15 described in the first embodiment. The manufacturing method of the display panel according to the second embodiment has a distinguishing feature, that is, the laminated film layer formation step is performed after the organic layer formation step. The functions and effects of steps in the second embodiment are substantially the same as those of the corresponding steps in the first embodiment, so a detailed description thereof is not repeated herein for brevity.

The present invention provides the display panel and the manufacturing method of the display panel. On the one hand, the stress of the layers is released by means of the patterned surface on the organic layer, and a risk of breakage of the TFE layer from bending of the display panel is lowered, thereby improving reliability of the TFE layer and enhancing optical performance of the display panel. On the other hand, by providing a laminated film layer between the adjacent organic layer and inorganic layer, adhesion between the layers is improved, the TFE layer has better water/oxygen barrier properties, thereby further improving reliability of the TFE layer.

It is to be understood that the above descriptions are merely the preferable embodiments of the present invention and are not intended to limit the scope of the present invention. Equivalent changes and modifications made in the spirit of the present invention are regarded as falling within the scope of the present invention.

What is claimed is:

1. A display panel, comprising:
a substrate; and
a thin film encapsulation layer disposed on one side of the substrate;
wherein the thin film encapsulation layer comprises:
a first inorganic layer disposed on a side surface of the substrate;
an organic layer disposed on one side of the first inorganic layer away from the substrate, the organic layer comprising a patterned surface;
a second inorganic layer disposed on one side of the organic layer away from the first inorganic layer; and
a laminated film layer disposed between the organic layer and the first inorganic layer or between the organic layer and the second inorganic layer;
wherein the laminated film layer comprises a dense layer and a transition layer, the dense layer is disposed on the first inorganic layer or the second inorganic layer, one side of the transition layer is attached to the dense layer, and another side of the transition layer is attached to the organic layer.

2. The display panel according to claim 1, wherein the organic layer comprises two or more protrusions protruding from the patterned surface.

3. The display panel according to claim 1, wherein the patterned surface is in contact with the laminated film layer or in contact with the second inorganic layer.

4. The display panel according to claim 1, wherein the dense layer is made of alumina and/or titanium oxide.

5. The display panel according to claim 1, wherein the transition layer is made of silicon oxide and/or silicon oxynitride.

6. The display panel according to claim 1, wherein a thickness of the dense layer is less than 200 nm, a thickness of the transition layer is less than 150 nm, and a refractive index of the transition layer is greater than 1.6.

7. A manufacturing method of a display panel, comprising steps as follows:
a substrate provision step for providing a substrate; and
a thin film encapsulation layer formation step for forming a thin film encapsulation layer on an upper surface of the substrate;
wherein the thin film encapsulation layer formation step comprises steps as follows:
a first inorganic layer formation step for forming a first inorganic layer on the upper surface of the substrate;
a laminated film layer formation step for forming a laminated film layer on an upper surface of the first inorganic layer;
an organic layer formation step for forming an organic layer on an upper surface of the laminated film layer and patterning a surface of the organic layer; and
a second inorganic layer formation step for forming a second inorganic layer on an upper surface of the organic layer.

8. The manufacturing method of the display panel according to claim 7, wherein the laminated film layer formation step comprises steps as follows:
a dense layer formation step for depositing a dense layer on the upper surface of the first organic layer by an atomic deposition method; and
a transition layer formation step for depositing a transition layer on the upper surface of the dense film layer by a chemical vapor deposition method;
wherein in the organic layer formation step, the organic layer is deposited on an upper surface of the transition layer, and a surface of the organic layer is patterned.

9. A manufacturing method of a display panel, comprising steps as follows:
a substrate provision step for providing a substrate; and
a thin film encapsulation layer formation step for forming a thin film encapsulation layer on an upper surface of the substrate;
wherein the thin film encapsulation layer formation step comprises steps as follows:
a first inorganic layer formation step for forming a first inorganic layer on the upper surface of the substrate;
an organic layer formation step for forming an organic layer on an upper surface of the first inorganic layer and patterning a surface of the organic layer;
a laminated film layer formation step for forming a laminated film layer on an upper surface of the organic layer; and
a second inorganic layer formation step for forming a second inorganic layer on the upper surface of the organic layer.

10. The manufacturing method of the display panel according to claim 9, wherein the laminated film layer formation step comprises steps as follows:
a transition layer formation step for depositing a transition layer on an upper surface of the first inorganic layer by a chemical vapor deposition method; and
a dense layer formation step for depositing a dense layer on an upper surface of the transition layer by an atomic deposition method;
wherein in the second inorganic layer formation step, a second inorganic layer is deposited on an upper surface of the laminated film layer.
